(19) United States
(12) Patent Application Publication
(10) Pub. No.: US 2020/0209297 A1
(43) Pub. Date: Jul. 2, 2020

(54) POWER TESTING SYSTEM AND TEST DEVICE

(71) Applicant: HOBBES & CO., LTD., New Taipei City (TW)

(72) Inventor: TSE-KANG HUANG, Taipei City (TW)

(21) Appl. No.: 16/351,482

(22) Filed: Mar. 12, 2019

(30) Foreign Application Priority Data
Dec. 26, 2018 (TW) 107147201

(51) Int. Cl. G01R 31/02; H01R 24/64; H01R 25/00; H04L 12/10

(52) U.S. Cl. CPC G01R 31/021; H04L 12/10; H01R 25/00; H01R 24/64

(57) ABSTRACT

A test device includes a first connector, a second connector, a first power direction control circuit electrically connected to the first connector, a second power direction control circuit electrically connected to the first power direction control circuit through a power transmission circuit, and a detecting module electrically connected to the power transmission circuit and detecting the electric energy transmitted by the power transmission circuit. The second power direction control circuit is electrically connected to the second connector. The power sourcing device transmits the power to the powered device through the first connector. The first power direction control circuit, the power transmission circuit, the second power direction control circuit, and the second connector of the test device.

### CROSS-REFERENCE TO RELATED PATENT APPLICATION

This application claims the benefit of priority to Taiwan Patent Application No. 107147201, filed on Dec. 26, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a test device, and more particularly to a PoE test device that does not interfere with the communication connection between a power sourcing device and a powered device

### BACKGROUND OF THE DISCLOSURE

A conventional Power over Ethernet (PoE) test device is disposed between the power sourcing device and a powered device, which hinders communication between the power sourcing device and the powered device. As a result of the communication being obstructed, power transmission often becomes a problem.

Certain solutions for the foregoing problem use a test device as a communication intermediary to firstly communicate with the power sourcing device, so as to then allow the power sourcing device to provide power. The electric energy can then be provided to the powered device. However, the electric energy at this time may not be in the power specification suitable for the powered device.

Therefore, providing a test device that does not interfere with communication and power transmission between the power sourcing device and the powered device has become an important issue in the industry.

### SUMMARY OF THE DISCLOSURE

In response to the above-referenced technical inadequacies, the present disclosure provides a test device. The test device is disposed between a power sourcing device and a powered device for detecting at least one voltage value and at least one current of an electric energy provided by the power sourcing device to the powered device. The test device includes a first connector, a second connector, a first power direction control circuit electrically connected to the first connector, a second power direction control circuit electrically connected to the first power direction control circuit through a power transmission circuit, and a detecting module electrically connected to the power transmission circuit and detecting the power transmitted by the power transmission circuit. The second power direction control circuit is electrically connected to the second connector, the power sourcing device transmits the power to the powered device through the first connector, the first power direction control circuit, the power transmission circuit, the second power direction control circuit, and the second connector of the test device.

In one aspect, the present disclosure provides a power testing system. The power testing system includes a power sourcing device, a powered device, and a test device. The test device is disposed between the power sourcing device and the powered device. The power sourcing device is connected to the test device through a first network cable, and the powered device is connected to the test device by a second network cable. The power sourcing device communicates with the powered device through the test device to obtain a power information, and the power sourcing device provides an electric energy to the powered device through the test device according to the power information. The test device inductively detects a voltage value of the electric energy. In another aspect, the present disclosure provides a test device. The test device is disposed between a power sourcing device and a powered device for detecting at least one voltage value and at least one current value of an electric energy provided by the power sourcing device to the powered device. The test device includes a first connector, a second connector electrically connected to the first connector by a power transmission circuit, and a detecting module electrically connected to the power transmission circuit and detecting the electric energy transmitted by the power transmission circuit. The power sourcing device transmits the electric energy to the powered device through the first connector of the test device, the power transmission circuit, and the second connector.

Therefore, the test device of the present disclosure allows the power sourcing device and the powered device to normally provide electric energy during the test. Moreover, the test device can determine the one-way power transmission or the two-way power transmission of the test device by using the first power direction control circuit and the second power direction control circuit, which can effectively enhance the convenience of the test.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic diagram of a power testing system according to an embodiment of the present disclosure. FIG. 2 is a schematic diagram of a test device according to an embodiment of the present disclosure.

FIG. 3 is another schematic diagram of a test device according to an embodiment of the present disclosure.

FIG. 4 is a schematic diagram of a test device connected to a power sourcing device and a powered device according to an embodiment of the present disclosure.

FIG. 5 is another schematic diagram of a test device connected to a power sourcing device and a powered device according to an embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

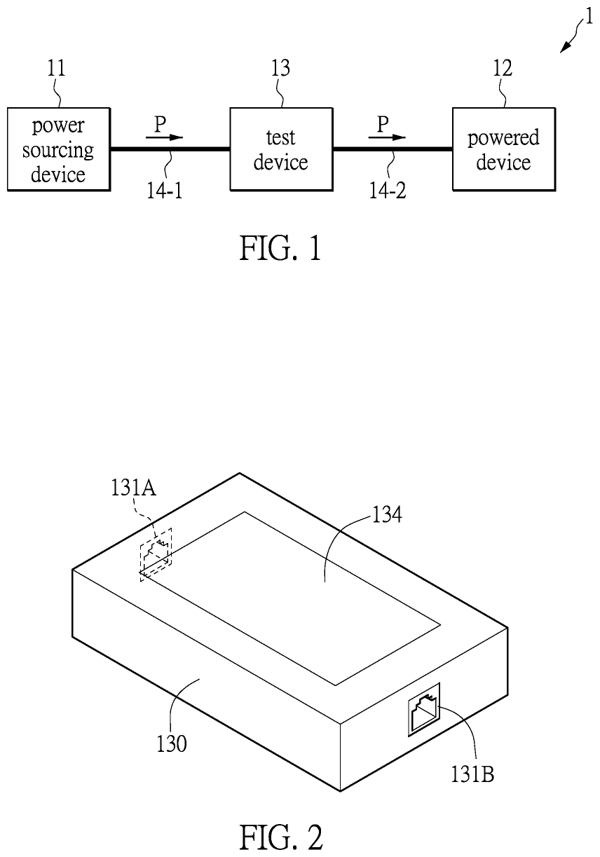

Referring to FIG. 1, a schematic diagram of a power testing system according to an embodiment of the present disclosure is shown.

In the embodiment, the power testing system 1 is a Power over Ethernet (PoE) testing system. The testing system 1 includes a power sourcing device 11, a powered device 12, and a test device 13. The power sourcing device 11 is connected to the test device 13 via a first network cable 14-1. The test device 13 is connected to the powered device 13 via a second network cable 14-2.

In the embodiment, the power sourcing device 11 communicates with the powered device 12 through the test device 13 to obtain a power information of the powered device 12. The power sourcing device 11 supplies an electric energy P to the powered device 12 through the test device 13 according to the power information of the powered device 12.

In the embodiment, the test device 13 detects a voltage value of the electric energy P in an inductive manner. In other words, the test device 13 provides a power transmission path for the power sourcing device 11 and the powered device 12 to communicate and transmit an electric energy P. The test device 13 does not obstruct the operation of the power sourcing device 11 and the powered device 12.

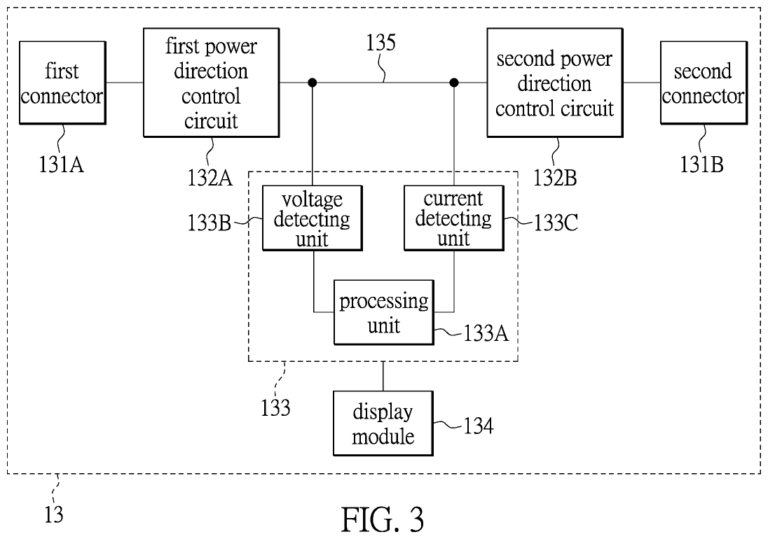

Referring to FIG. 2 and FIG. 3, FIG. 2 is a schematic diagram of a test device according to an embodiment of the present disclosure. FIG. 3 is another schematic diagram of a test device according to an embodiment of the present disclosure.

The test device 13 includes a housing 130, a first connector 131A, a second connector 131B, a first power direction control circuit 132A, a second power direction control circuit 132B, and a detecting module 133, a display module 134 and a power transmission circuit 135.

In the embodiment, the first connector 131A, the second connector 131B, the first power direction control circuit 132A, the second power direction control circuit 132B, the detecting module 133, and the power transmission circuit 135 are disposed in the housing 130.

The display module 134 is disposed at one side of the housing 130 for allowing convenient viewing of an information related to the electric energy P provided by the power sourcing device 11 by the user.

In the embodiment, the first connector 131A and the second connector 131B are disposed on at least one side of the housing 130. In other words, the first connector 131A and the second connector 131B may be disposed on the same side of the housing 130, as long as said side can accommodate the first connector 131A and the second connector 131B.

In the embodiment, the first connector 131A and the second connector 131B are the RJ45 connectors.

As shown in FIG. 2, the first connector 131A and the second connector 131B are respectively disposed on two opposite sides of the housing 130. This arrangement is convenient for connecting the test device 13, the power sourcing device 11, and the powered device 12 and performing a test procedure.

In other embodiments, the first connector 131A and the second connector 131B can be disposed on two adjacent sides of the housing 130, but the structural arrangement thereof can be adjusted according to actual requirements and is not limited in the present disclosure.

In the embodiment, the first connector 131A is electrically connected to the first power direction control circuit 132A. The first power direction control circuit 132A is electrically connected to the second power direction control circuit 132B through the power transmission circuit 135. The second power direction control circuit 132B is electrically connected to the second connector 131B.

The detecting module 133 is electrically connected to the power transmission circuit 135. In the embodiment, the power transmission circuit 135 includes a copper foil and a power transmission line which are laid on a circuit board, but the structural arrangement thereof can be adjusted according to actual requirements and is not limited in the present disclosure.

As described previously, the detecting module 133 detects the electric energy P transmitted by the power transmission circuit 135 in an inductive manner. In other words, the detecting module 133 detects the voltage value and the current value of the power transmission circuit 135 by magnetic field induction. In other words, the test device 13 does not participate in communication and power transmission between the power sourcing device 11 and the powered device 12. Therefore, a test procedure is not performed when the test device 13 of the present disclosure is disposed between the power sourcing device 11 and the powered device 12, and obstructs power transmission or communication between the power sourcing device 11 and the powered device 12.

In other words, the power sourcing device 11 transmits electric energy P to the powered device 12 through the first connector 131A, the first power direction control circuit 132A, the power transmission circuit 135, the second power direction control circuit 132B, and the second connector 131B of the test device 13.

In addition, the communication path between the power sourcing device 11 and the powered device 12 also uses the first connector 131A of the test device 13, the first power direction control circuit 132A, the power transmission circuit 135, the second power direction control circuit 132B, and a second connector 131B.

In other words, both the communication path and the power transmission path of the power sourcing device 11 and the powered device 12 are not affected by the test device 13.

However, in the embodiment, the detecting module 133 is electrically connected to the power transmission circuit 135 for acquiring a portion of the power to drive the detecting module 133 and the display module 134. In addition, before the power sourcing device 11 normally provides the electric energy P to the powered device 12, the test device 13 does not obtain power for testing. In other words, the test device 13 may obtain power to drive an internal circuit, such as the detecting module 133, after the power sourcing device 11 normally provides the power to the powered device 12 to perform a test procedure.

In the embodiment, the detecting module 133 includes a processing unit 133A, a voltage detecting unit 133B, and a current detecting unit 133C. The voltage detecting unit 133B is configured to inductively detect the voltage value of the electric energy P. The current detecting unit 133C is configured to detect the current value of the electric energy P. The processing unit 133A calculates a power value of the electric energy P according to the voltage value detected by the voltage detecting unit 133B and the current value detected by the current detecting unit 133C.

In the embodiment, the voltage value, the current value, and the calculated power value detected by the detecting module 133 are displayed on the display module 134. In the embodiment, the display module 134 includes a liquid crystal display device, an organic light emitting diode display device, and a light emitting diode display device.

### Second Embodiment

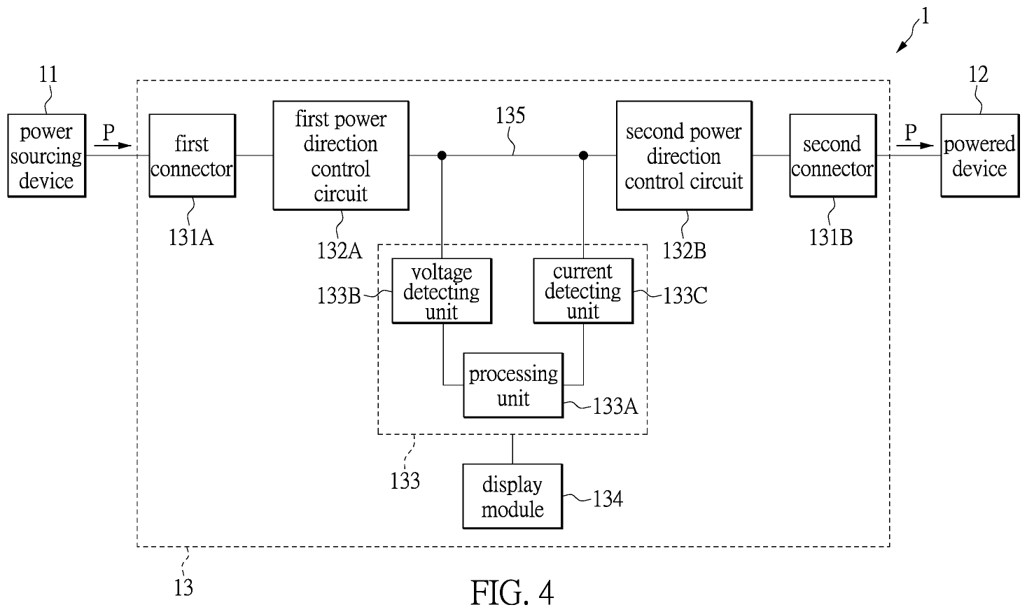

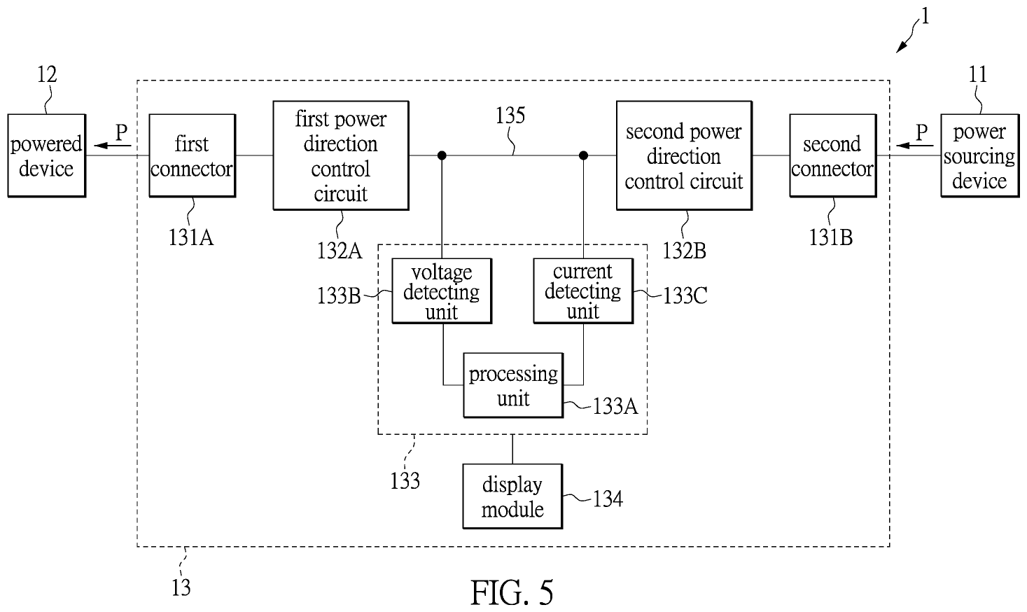

Referring to FIG. 4 and FIG. 5, FIG. 4 is a schematic diagram of a test device connected to a power sourcing device and a powered device according to an embodiment of the present disclosure. FIG. 5 is another schematic diagram of a test device connected to a power sourcing device and a powered device according to an embodiment of the present disclosure.

In the embodiment, the first power direction control circuit 132A and the second power direction control circuit 132B of the test device 13 respectively include a dual-direction conduction circuit and a single-direction conduction circuit.

The first power direction control circuit 132A and the second power direction control circuit 132B of the test device 13 are respectively a dual-direction conduction circuit. The power sourcing device 11 can be connected to the first power direction control circuit 132A or the second power direction control circuit 132B, respectively. The powered device 12 is connected to the second power direction control circuit 132B or the first power direction control circuit 132A.

As shown in FIG. 4, the power sourcing device 11 and the powered device 12 are respectively connected to the first connector 131A and the second connector 131B of the test device 13 for communication and providing electric energy.

As shown in FIG. 5, the power sourcing device 11 and the powered device 12 are respectively connected to the second connector 131B of the test device 13 and the first connector 131A for communication and providing electric energy.

In the embodiment, the dual-conduction circuit refers to a circuit that can transmit electric energy bidirectionally, and the single-direction conduction circuit refers to a circuit that can transmit electric energy only in a single direction. In the embodiment, the first power direction control circuit 132A and the second power direction control circuit 132B may be formed by a bridge rectifier circuit, but is not limited in the present disclosure.

In other embodiments, the first power direction control circuit 132A and the second power direction control circuit 132B may not be included in the test device 13. In other words, the power sourcing device 11 performs communication and power transmission only through the first connector 131A, the power transmission circuit 135, and the second connector 131B.

In conclusion, the test device of the present disclosure allows the power sourcing device and the powered device to normally provide the electric energy during the test. Moreover, the test device can determine whether the one-way power transmission or the two-way power transmission of the test device is to be used by virtue of the first power direction control circuit and the second power direction control circuit, which can effectively enhance the convenience of the test.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated.

Alternative embodiments will become apparent to those skilled in the art to which the present disclosure pertains without departing from its spirit and scope.

What is claimed is:

1. A test device disposed between a power sourcing device and a powered device for detecting at least one voltage value and at least one current of an electric energy provided by the power sourcing device to the powered device, the test device comprising:
a first connector;
a second connector;
a first power direction control circuit electrically connected to the first connector;
a second power direction control circuit electrically connected to the first power direction control circuit through a power transmission circuit, wherein the second power direction control circuit is electrically connected to the second connector, the power sourcing device transmits the electric energy to the powered device through the first connector, the first power direction control circuit, the power transmission circuit, the second power direction control circuit, and the second connector of the test device; and
a detecting module electrically connected to the power transmission circuit and detecting the electric energy transmitted by the power transmission circuit.

2. The test device of claim 1, wherein the power sourcing device communicates with the powered device and provides the electric energy to the powered device through the first connector, the first power direction control circuit, and the power transmission circuit, the second power direction control circuit, and the second connector of the test device.

3. The test device of claim 1, wherein the detecting module includes:
a voltage detecting unit inductively detecting the voltage value of the electric energy; and
a current detecting unit for detecting the current value of the electric energy;
wherein a processing unit calculates a power value of the electric energy according to the voltage value detected by the voltage detecting unit and the current value detected by the current detecting unit.

4. The test device described in claim 3, further comprising:
a display module displaying the voltage value detected by the detecting module, the current value, and the power value; and
a housing, the first connector and the second connector being disposed on at least one side of the housing;
wherein the first power direction control circuit, the second power direction control circuit, and the detecting module are disposed in the housing;
wherein the display module is disposed at one side of the housing.

5. The test device of claim 4, wherein the first connector and the second connector are disposed on two adjacent sides or two opposite sides of the housing.

6. The test device of claim 4, wherein the first power direction control circuit and the second power direction control circuit are respectively a dual-direction conduction circuit or a single-direction conduction circuit.

7. A power testing system, comprising:
a power sourcing device;
a powered device; and
a test device disposed between the power sourcing device and the powered device, the power sourcing device being connected to the test device through a first network cable, and the powered device being connected to the test device through a second network cable;
wherein the power sourcing device communicates with the powered device through the test device to obtain a power information, and the power sourcing device provides an electric energy to the powered device through the test device according to the power information;
wherein the test device inductively detects a voltage value of the electric energy.

8. The power testing system of claim 7, wherein the test device includes a first connector and a second connector, and the power sourcing device and the powered device are respectively connected to the first connector and the second connector of the test device for communication and providing power.

9. The power testing system of claim 8, wherein the power sourcing device and the powered device are respectively connected to the second connector of the test device and the first connector of the test device for communication and providing power.

10. The power testing system of claim 8, wherein the test device further includes:
a first power direction control circuit electrically connected to the first connector;
a second power direction control circuit electrically connected to the first power direction control circuit through a power transmission circuit, wherein the second power direction control circuit is electrically connected to the second connector, the power sourcing device transmits the electric energy to the powered device or communicates with the powered device through the first connector, the first power direction control circuit, the power transmission circuit, the second power direction control circuit, and the second connector of the test device; and
a detecting module electrically connected to the power transmission circuit and detecting the electric energy transmitted by the power transmission circuit.

11. The power testing system of claim 10, wherein the detecting module including:
a voltage detecting unit inductively detecting the voltage value of the electric energy;
a current detecting unit detecting the current value of the electric energy; and
a processing unit calculating a power value of the electric energy according to the voltage value detected by the voltage detecting unit and the current value detected by the current detecting unit.

12. The power testing system of claim 11, wherein the test device further includes:
a display module displaying the voltage value, the current value, and the power value detected by the detecting module; and
a housing, the first connector and the second connector being disposed on at least one side of the housing;
wherein the first power direction control circuit, the second power direction control circuit, and the detecting module are disposed in the housing;
wherein the display module is disposed at one side of the housing.

13. The power testing system of claim 12, wherein the first connector and the second connector are disposed on two adjacent sides of the housing or two opposite sides of the housing.

14. The power testing system of claim 12, wherein the first power direction control circuit and the second power direction control circuit are respectively a dual-direction conduction circuit or a single-direction conduction circuit.

15. A test device disposed between a power sourcing device and a powered device for detecting at least one voltage value and at least one current value of an electric energy provided by the power sourcing device to the powered device, the test device comprising:
a first connector;
a second connector electrically connected to the first connector by a power transmission circuit, wherein the power sourcing device transmits the electric energy to the powered device through the first connector of the test device, the power transmission circuit, and the second connector; and
a detecting module electrically connected to the power transmission circuit and detecting the electric energy transmitted by the power transmission circuit.

16. The test device of claim 15, further comprising:
a first power direction control circuit electrically connected to the first connector; and
a second power direction control circuit electrically connected to the first power direction control circuit by the power transmission circuit, wherein the second power direction control circuit is electrically connected to the second connector, the power sourcing device transmits the electric energy to the powered device or communicates with the powered device through the first connector, the first power direction control circuit, the power transmission circuit, the second power direction control circuit, and the second connector of the test device.

17. The test device of claim 16, wherein the detecting module including:
a voltage detecting unit inductively detecting the voltage value of the electric energy;
a current detecting unit for detecting the current value of the electric energy; and
a processing unit calculating a power value of the electric energy according to the voltage value detected by the voltage detecting unit and the current value detected by the current detecting unit.

18. The test device of claim 17, further comprising:
a display module displaying the voltage value, the current value, and the power value detected by the detecting module; and
a housing, the first connector and the second connector being disposed on at least one side of the housing;
wherein the first power direction control circuit, the second power direction control circuit, and the detecting module are disposed in the housing;
wherein the display module is disposed at one side of the housing.

19. The test device of claim 18, wherein the first connector and the second connector are disposed on two adjacent sides of the housing or the opposite sides of the housing.

20. The test device of claim 18, wherein the first power direction control circuit and the second power direction control circuit are respectively a dual-direction conduction circuit or a single-direction conduction circuit.
